(19) United States
(12) Patent Application Publication
(10) Pub. No.: US 2008/0129365 A1
(43) Pub. Date: Jun. 5, 2008

(54) Level Shift Circuit with Low-Voltage Input Stage

(75) Inventor: Yu Jui Chang, Tainan County (TW)

Correspondence Address: WPAT, PC;INTELLECTUAL PROPERTY ATTORNEYS, 2030 MAIN STREET, SUITE 1300, IRVINE, CA, 92614, US

(73) Assignee: HIMAX TECHNOLOGIES LIMITED, Tainan County (TW)

(21) Appl. No.: 11/566,667

(22) Filed: Dec. 4, 2006

(51) Int. Cl. H03L 5/00

(52) U.S. Cl. 327/333

(57) ABSTRACT

A level shift circuit with a low-voltage input stage, converting an input signal to an output signal, includes at least one level shift unit. The level shift unit includes a first transistor receiving a supply voltage and a first gate control signal to generate a second gate control signal, a second transistor receiving the supply voltage and the second gate control signal to generate the first gate control signal, a third transistor receiving the input signal to ground the second gate control signal, a fourth transistor receiving an inverted signal of the input signal to ground the first gate control signal, a fifth transistor receiving a first control signal to transfer the second gate control signal to the third transistor, and a sixth transistor receiving the first control signal to transfer the first gate control signal to the fourth transistor. The level of the output signal is determined by that of the first control signal.

### BACKGROUND OF THE INVENTION

1. Field of the Invention

The present invention relates to a level shift circuit, and more particularly, to a level shift circuit with a low-voltage input stage.

2. Description of the Related Art

FIG. 1 shows a conventional level shift circuit 1, used in a scan driver of an LCD (Liquid Crystal Display) module, to convert a low-voltage digital signal into a high-voltage digital signal. The level shift circuit 1 includes four HV (high voltage) MOS transistors T1-T4 coupled to each other. The sources of two HV PMOS transistors T1 and T2 receive a first voltage VDDA (e.g., 9 volts or 14 volts). The sources and bulks of two HV NMOS transistors T3 and T4 are connected to a ground level VSSA. When an input signal IN with a low-voltage high logic state (e.g., 3.3 volts) is applied at the gate of the HV NMOS transistor T3, the HV PMOS transistor T2 is turned on by the gate thereof being grounded through the conductive HV NMOS transistor T3. The HV NMOS transistor T4 is turned off by an inverted signal INB (an inverted signal of the input signal IN) with a low-voltage low logic state (i.e., 0 volts) applied at the gate thereof. Therefore, an output signal DDX exhibits a high-voltage high logic state of the first voltage VDDA. In the meantime, the HV PMOS transistor T1 is turned off with the gate thereof at the first voltage VDDA. That is, a low-voltage high logic state (e.g., 3.3 volts) is converted into a high-voltage high logic state (e.g., 9 volts or 14 volts) by the level shift circuit 1. When the input signal IN switches to the low-voltage low logic state (i.e., 0 volts) and the inverted signal INB switches to the low-voltage high logic state (e.g., 3.3 volts), the HV NMOS transistor T3 is turned off and the HV NMOS transistor T4 is turned on. The HV PMOS transistor T1 is turned on by the gate thereof being grounded through the conductive HV NMOS transistor T4, and the HV PMOS transistor T2 is turned off by the gate thereof receiving the first voltage VDDA through the conductive HV NMOS transistor T1. Therefore, the output signal DDX exhibits a high-voltage low logic state (i.e., 0 volts). That is, a low-voltage low logic state (i.e., 0 volts) is converted into a high-voltage low logic state (i.e., 0 volts) by the level shift circuit 1.

When the inverted signal INB switches from the low-voltage low logic state to the low-voltage high logic state in some low-voltage applications (i.e., switches from 0 volts to around 1.6 volts), the HV NMOS transistor T4 that has a threshold voltage of around 1.4 volts is not easily turned on. This results in some issues. First, the time in which the output signal DDX switches from the high logic state to the low logic state is increased. Second, it is possible to generate a DC current path at a moment when all four HV transistors T1-T4 are turned on. Third, a large current dissipates due to the first two issues. Fourth, switching states fails due to the DC current latch. One conventional solution proposed is to add a charge pump to boost the voltage level of the input signal IN and the inverse signal INB from 1.6 volts to 3.2 volts, for example. However, the nature of the low-voltage application causes the accumulated charge by the charge pump to be limited. Consequently, a large capacitor (equivalent to a large area) is needed for this solution.

### SUMMARY OF THE INVENTION

One aspect of the present invention is to provide a level shift circuit with a low-voltage input stage, by adding two LV (low voltage) MOS transistors, to enhance the capability of switching states in a low-voltage application such as a source river of an LCD panel.

The present invention discloses a level shift circuit with a low-voltage input stage. The level shift circuit with a low-voltage input stage includes at least one level shift unit converting an input signal into an output signal. The level shift unit includes a first transistor, a second transistor, a third transistor, a fourth transistor, a fifth transistor, and a sixth transistor. The first transistor receives a supply voltage and a first gate control signal to generate a second gate control signal. The second transistor receives the supply voltage and the second gate control signal to generate the first gate control signal. The third transistor receives the input signal to ground the second gate control signal. The fourth transistor receives an inverted signal of the input signal to ground the first gate control signal. The fifth transistor receives a first control signal to transfer the second gate control signal to the third transistor. The sixth transistor receives the first control signal to transfer the first gate control signal to the fourth transistor.

### BRIEF DESCRIPTION OF THE DRAWINGS

The invention will be described according to the appended drawings in which:

FIG. 1 shows a conventional level shift circuit;

FIG. 2 shows a first embodiment of a level shift circuit with a low-voltage input stage according to the present invention; and

FIG. 3 shows a second embodiment of a level shift circuit with a low-voltage input stage according to the present invention.

### DETAILED DESCRIPTION OF THE INVENTION

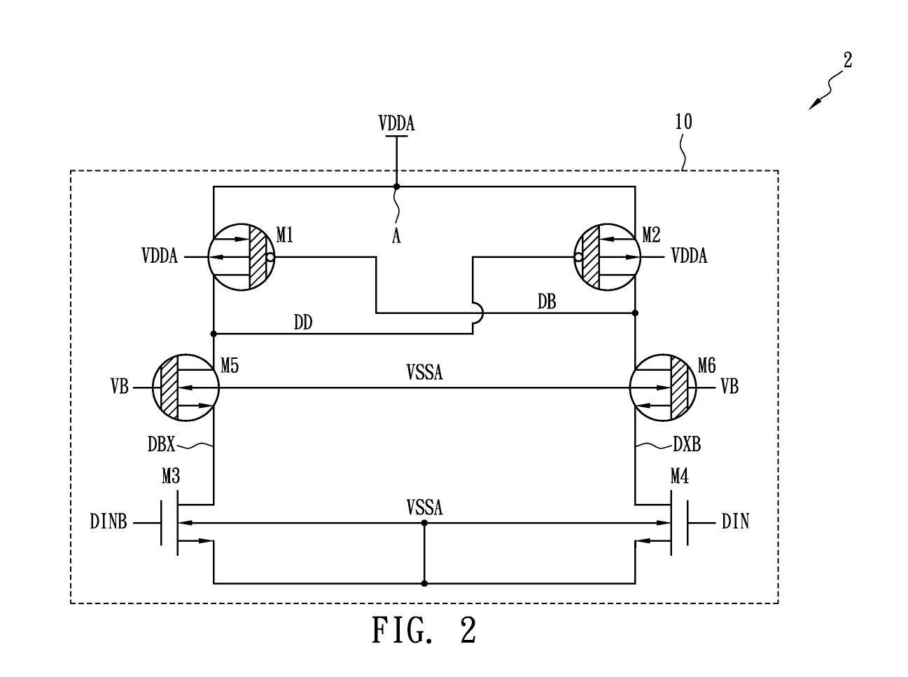

FIG. 2 shows a first embodiment of a level shift circuit 2 with a low-voltage input stage according to the present invention. The level shift circuit 2 with a low-voltage input stage includes a level shift unit 10 converting an input signal DINB into an output signal DXB. The level shift unit 10 includes a first transistor M1, a second transistor M2, a third transistor M3, a fourth transistor M4, a fifth transistor M5, and a sixth transistor M6. The first, the second, the fifth, and the sixth transistors M1, M2, M5, M6 are HV (high voltage) transistors (each shown as a circle with a slashed area). The third and the fourth transistors M3, M4 are LV (low voltage) transistors. The bulk and the source of the third transistor M3, the bulk and the source of the fourth transistor M4, the bulk of the fifth transistor M5, and the bulk of the sixth transistor M6 are connected to a ground voltage VSSA. The bulks of the first and the second transistors M1, M2 are connected to a supply voltage VDDA (e.g., 9 volts or 14 volts, which is commonly used as the high logic state for analog signals in a source driver of an LCD panel). The second transistor M2 is coupled to the source of the first transistor M1 through the source thereof. The third transistor M3 is coupled to the source of the fifth transistor M5 through the drain thereof. The fourth transistor M4 is coupled to the source of the sixth transistor M6 through the drain thereof.

The operation of the level shift circuit 2 with a low-voltage input stage of FIG. 2 is given as follows. The case of a first control signal VB with a sufficient high voltage to turn on the fifth and the sixth transistors M5 and M6 is considered below. When an input signal DINB is in a low-voltage high logic state (e.g., 3.3 volts), and therefore, an inverted signal DIN of the input signal DINB is in a low-voltage low logic state (i.e., 0 volts), the second transistor M2 is turned on by the gate thereof being grounded through the conductive fifth transistor M5 and the conducive third transistor M3. Consequently, the output signal DXB retrieved from the drain of the fourth transistor M4 exhibits a high-voltage high logic state with a level equal to the first control signal VB minus the threshold voltage of the sixth transistor M6. Therefore, the level of the output signal DXB is clamped by the level of the first control signal VB, and the level of the first control signal VB could be designed appropriately to determine the level of the output signal DXB and then to protect the LV fourth transistor M4. In the meantime, the first transistor M1 is turned off by the gate thereof receiving the first gate control signal DB exhibiting the high logic state of the supply voltage VDDA. That is, the input signal DINB with the low-voltage high logic state (i.e., 3.3 volts) is converted into the output signal DXB with the high-voltage high logic state (i.e., VDDA) by the level shift circuit 2 with a low-voltage input stage. When the input signal DINB switches to the low-voltage low logic state, and therefore, the inverted signal DIN of the input signal DINB is in the low-voltage high logic state, the first transistor M1 is turned on by the gate thereof being grounded through the conductive sixth transistor M6 and the conducive fourth transistor M4. Consequently, the output signal DXB retrieved from the drain of the fourth transistor M4 exhibits a high-voltage low logic state of the ground voltage VSSA. In the meantime, the second transistor M2 is turned off by the gate thereof receiving a second gate control signal DD exhibiting the high logic state of the supply voltage VDDA. That is, the input signal DINB with the low-voltage low logic state (i.e., 0 volts) is converted into the output signal DXB with the high-voltage low logic state (i.e., VSSA) by the level shift circuit 2 with a low-voltage input stage.

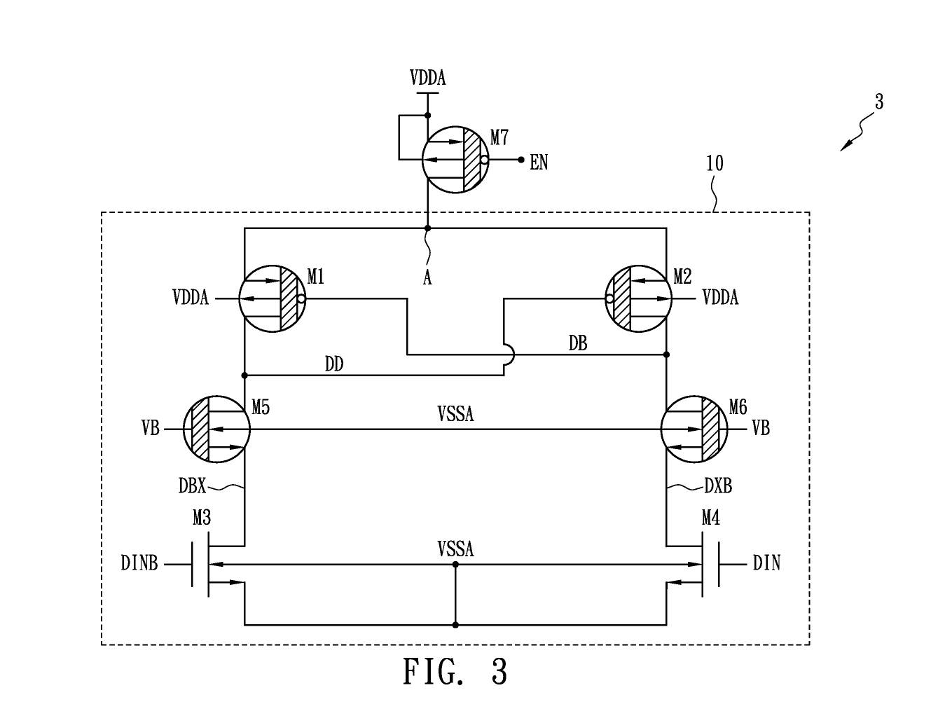

FIG. 3 shows a second embodiment of a level shift circuit 3 with a low-voltage input stage according to the present invention. Compared with the first embodiment in FIG. 2, the second embodiment further includes a switch M7 (a PMOS transistor in the current embodiment). The PMOS transistor M7 receives a second control signal EN to transfer the supply voltage VDDA to the first transistor M1 and the second transistor M2. The second control signal EN is generated so that the PMOS transistor M7 is turned off upon transitions of the input signal DINB. The PMOS transistor M7 is coupled to the supply voltage VDDA through the source thereof and receives the second control signal EN at the gate thereof. The operation of the second embodiment is similar to that of the first embodiment, and it is omitted here.

For the above embodiments, when the level shift circuits with a low-voltage input stage of the present invention are used in a source driver of an LCD panel, the supply voltage VDDA would be used as a high logic state for analog signals. In addition, the source and the drain of the fifth transistor M5 can be swapped and those of the sixth transistor M6 can also be swapped.

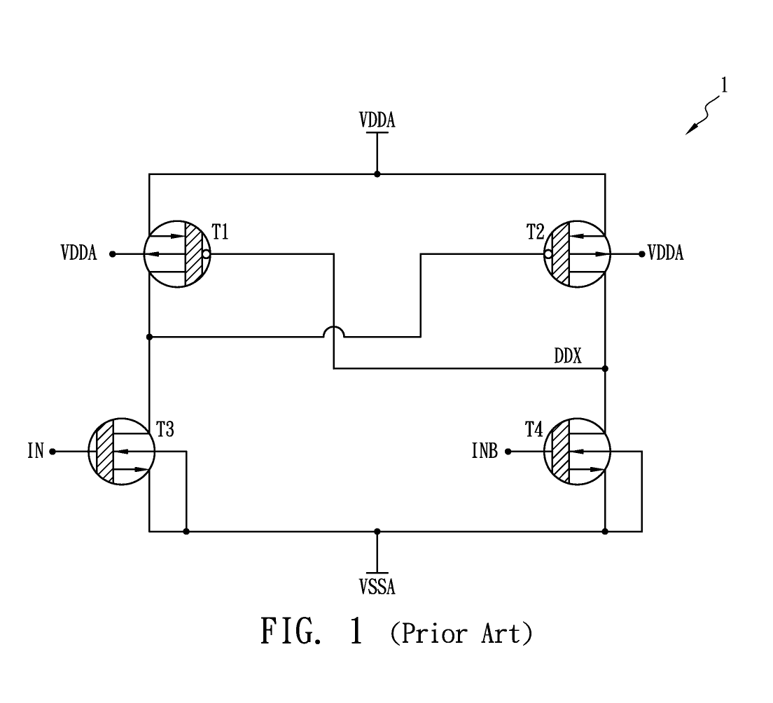

According to the above embodiments, two LV MOS transistors having lower threshold voltages than HV MOS transistors are added and the input stage of the level shift circuit of the present invention still can receive the low-voltage inputs without suffering from the issues of the conventional level shift circuit of FIG. 1. Consequently, the capability of switching states of the level shift circuit of the present invention is enhanced. Additionally, the two LV MOS transistors are protected from high-voltage damage from the supply voltage by introducing the first control signal to determine the level of the output signal.

The above-described embodiments of the present invention are intended to be illustrative only. Numerous alternative embodiments may be devised by those skilled in the art without departing from the scope of the following claims.

What is claimed is:

1. A level shift circuit with a low-voltage input stage, comprising:
at least one level shift unit converting an input signal of a low voltage range into an output signal, the level shift unit comprising:
a first transistor receiving a supply voltage of a high voltage range and a first gate control signal to generate a second gate control signal;
a second transistor receiving the supply voltage and the second gate control signal to generate the first gate control signal;
a third transistor receiving the input signal to ground the second gate control signal;
a fourth transistor receiving an inverted signal of the input signal to ground the first gate control signal;
a fifth transistor receiving a first control signal to transfer the second gate control signal to the third transistor;
a sixth transistor receiving the first control signal to transfer the first gate control signal to the fourth transistor; and
wherein the first control signal is a constant and configured to turn on the fifth transistor and the sixth transistor, so that the third transistor and the fourth transistor are operated in the low-voltage range.

2. The level shift circuit with a low-voltage input stage of claim 1, further comprising a switch receiving a second control signal to transfer the supply voltage to the first and the second transistors.

3. The level shift circuit with a low-voltage input stage of claim 2, wherein the switch is a transistor coupled to the supply voltage through the source thereof and receiving the second control signal at the gate thereof.

4. The level shift circuit with a low-voltage input stage of claim 1, wherein the output signal is retrieved from the drain of the fourth transistor, and the level of the output signal is higher than the level of the input signal when the input signal is in a high logic state.

5. The level shift circuit with a low-voltage input stage of claim 1, wherein the level of the output signal is determined by the level of the first control signal.

6. The level shift circuit with a low-voltage input stage of claim 1, wherein the first, the second, the fifth, and the sixth transistors are high-voltage MOS transistors, and the third and the fourth transistors are low-voltage MOS transistors.

7. The level shift circuit with a low-voltage input stage of claim 1, wherein the bulk and the source of the third transistor, the bulk and the source of the fourth transistor, the bulk of the fifth transistor, and the bulk of the sixth transistor are connected to a ground voltage.

8. The level shift circuit with a low-voltage input stage of claim 1, wherein the bulks of the first transistor and the second transistor are connected to the supply voltage.

9. The level shift circuit with a low-voltage input stage of claim 1, wherein the second transistor is coupled to the source of the first transistor through the source thereof.

10. The level shift circuit with a low-voltage input stage of claim 1, wherein the third transistor is coupled to the source of the fifth transistor through the drain thereof, and the fourth transistor is coupled to the source of the sixth transistor through the drain thereof.

11. The level shift circuit with a low-voltage input stage of claim 1, which is used in a source driver of an LCD panel.

12. The level shift circuit with a low-voltage input stage of claim 1, wherein the supply voltage (VDDA) is used as the high logic state for analog signals.

13. A level shift circuit comprising:
a first transistor having a source receiving a first voltage of a high voltage range;
a second transistor having a source receiving the first voltage, a drain coupled to a gate of the first transistor and a gate coupled to a drain of the first transistor;
a third transistor having a source receiving a second voltage and a gate receiving an input signal;
a fourth transistor having a source receiving the second voltage and a gate receiving an inverted signal of the input signal;
a fifth transistor having a gate receiving a first control signal, a first source/drain coupled to the drain of the first transistor and a second source/drain coupled to the drain of the third transistor;
a sixth transistor having a gate receiving the first control signal, a first source/drain coupled to the drain of the second transistor and a second source/drain coupled to the drain of the fourth transistor; and
wherein the first control signal is a constant and configured to turn on the fifth transistor and the sixth transistor, so that the third transistor and the fourth transistor are operated in the low-voltage range.

14. The level shift circuit of claim 13, wherein the first control signal is generated so that voltages on the drains of the third and fourth transistors are lower than a predetermined level.

15. The level shift circuit of claim 14, further comprising a switch having one end receiving the first voltage and the other end coupled to the sources of the first and second transistors, and controlled by a second control signal, wherein the second control signal is generated so that the switch is turned off upon transitions of the input signal.

16. The level shift circuit of claim 15, wherein the first, the second, the fifth, and the sixth transistors are high-voltage MOS transistors, and the third and the fourth transistors are low-voltage MOS transistors.
